(19) United States
(12) Patent Application Publication
(10) Pub. No.: US 2026/0020281 A1
(43) Pub. Date: Jan. 15, 2026

(54) SEMICONDUCTOR STRUCTURE

(71) Applicant: UNITED MICROELECTRONICS CORP., Hsin-Chu City (TW)

(72) Inventors: Ming-Hsiang Tu, Tainan City (TW); Ming-Hua Tsai, Tainan City (TW); Chun-Lin Chen, Tainan City (TW); Chun-Wen Cheng, New Taipei City (TW); Ya-Hsin Huang, Tainan City (TW); Yung-Fang Yang, Chiayi City (TW)

(73) Assignee: UNITED MICROELECTRONICS CORP., Hsin-Chu City (TW)

(21) Appl. No.: 18/798,843

(22) Filed: Aug. 9, 2024

(30) Foreign Application Priority Data
Jul. 11, 2024 (CN) 202410924843.4

(51) Int. Cl. H01L 29/78; H01L 27/088; H01L 29/06; H01L 29/40; H01L 29/423

(52) U.S. Cl. CPC H10D 30/65; H10D 30/62; H10D 62/116; H10D 64/112; H10D 64/519; H10D 84/834

(57) ABSTRACT

A semiconductor structure includes a substrate with a plurality of fins, a first well, and a second well in the substrate. The plurality of fins partially overlaps the first well and partially overlaps the second well. An epitaxial source region is arranged on the plurality of fins in the first well, and an epitaxial drain region is arranged on the plurality of fins in the second well. A gate is arranged on the plurality of fins between the epitaxial source region and the epitaxial drain region. A trench isolation region is disposed in the second well between the gate and the epitaxial drain region. A slot contact is disposed on the trench isolation region.

### BACKGROUND OF THE INVENTION

### 1. Field of the Invention

The present invention relates to the field of semiconductor technology, and in particular to an improved high-voltage metal oxide semiconductor (MOS) transistor structure.

### 2. Description of the Prior Art

Miniaturization and performance enhancement are the cornerstones of advancement in semiconductor technology. This relentless pursuit drives improvements in speed, efficiency, integration density, and cost per unit area. As the technology matures, high-power devices have found their way into diverse electronic products across various fields.

Laterally diffused metal-oxide semiconductor (LDMOS) and extended drain metal-oxide semiconductor (EDMOS) transistors are widely used as driving devices in high-voltage or high-power power management integrated circuits (PMICs). On-resistance (Ron) is a critical parameter for these devices, directly impacting power consumption—lower Ron translates to lower power usage. This characteristic is especially crucial for portable ICs. Consequently, improving the ratio of Ron to breakdown voltage (Ron/BVD) is a key objective in LDMOS and EDMOS development.

### SUMMARY OF THE INVENTION

It is one object of the present invention to provide an improved high-voltage MOS transistor structure to solve the deficiencies or shortcomings of the existing technology.

One aspect of the invention provides a semiconductor structure including a substrate having a plurality of fins thereon, wherein the plurality of fins extends along a first direction; a first well having a first conductive type disposed in the substrate; a second well having a second conductive type disposed in the substrate, wherein the plurality of fins partially overlaps with the first well and partially overlaps with the second well; an epitaxial source region having the second conductive type disposed on the plurality of fins within the first well; an epitaxial drain region having the second conductive type disposed on the plurality of fins within the second well, wherein the epitaxial drain region is spaced apart from the epitaxial source region; a gate disposed on the plurality of fins between the epitaxial source region and the epitaxial drain region, wherein the gate extends along a second direction; a trench isolation region disposed within the second well between the gate and the epitaxial drain region, wherein the trench isolation region extends along the second direction and cuts off the plurality of fins between the gate and the epitaxial drain region; and a slot contact disposed on the trench isolation region and extending along the second direction.

According to some embodiments, the gate does not overlap with the trench isolation region when viewed from above.

According to some embodiments, the gate is electrically connected to the slot contact.

According to some embodiments, the gate is not connected to the slot contact, wherein the gate is electrically coupled to a gate voltage and the slot contact is electrically coupled to a contact voltage.

According to some embodiments, the slot contact has a grid structure.

According to some embodiments, the slot contact comprises at least two parallel sub-contacts.

According to some embodiments, the trench isolation region has a top surface that is lower than a top surface of the epitaxial source region and a top surface of the epitaxial drain region.

According to some embodiments, the second well is contiguous with the first well.

According to some embodiments, the first conductivity type is P type and the second conductivity type is N type.

According to some embodiments, the gate is a metal gate.

Another aspect of the invention provides a semiconductor structure including a substrate having a plurality of fins thereon, wherein the plurality of fins extends along a first direction; a first well having a first conductive type disposed in the substrate; a second well having a second conductive type disposed in the substrate, wherein the plurality of fins partially overlaps with the first well and partially overlaps with the second well; an epitaxial source region having the second conductive type disposed on the plurality of fins within the first well; an epitaxial drain region having the second conductive type disposed on the plurality of fins within the second well, wherein the epitaxial drain region is spaced apart from the epitaxial source region; a gate disposed on the plurality of fins between the epitaxial source region and the epitaxial drain region, wherein the gate extends along a second direction; a plurality of trench isolation regions disposed within the second well between the plurality of fins, wherein the plurality of trench isolation regions extends along the first direction; and a plurality of slot contacts respectively disposed on the plurality of trench isolation regions and extending along the first direction.

According to some embodiments, the plurality of trench isolation regions is disposed in an extended region between the gate and the epitaxial drain region, and wherein the gate does not overlap with the plurality of trench isolation regions when viewed from above.

According to some embodiments, the gate is electrically connected to the plurality of slot contacts.

According to some embodiments, the gate is not connected to the plurality of slot contacts, wherein the gate is electrically coupled to a gate voltage and the plurality of slot contacts is electrically coupled to a contact voltage.

According to some embodiments, the plurality of slot contacts extends into the plurality of trench isolation regions, respectively.

According to some embodiments, the plurality of slot contacts is in parallel with the plurality of fins.

According to some embodiments, the plurality of trench isolation regions has a top surface that is coplanar with a top surface of the epitaxial source region, a top surface of the epitaxial drain region, and a top surface of the plurality of fins within the extended region.

According to some embodiments, the second well is contiguous with the first well.

According to some embodiments, the first conductivity type is P type and the second conductivity type is N type.

According to some embodiments, the gate is a metal gate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a partial top view of a semiconductor structure according to an embodiment of the present invention.

FIG. 2 is a schematic cross-sectional view taken along line I-I′ in FIG. 1.

FIG. 3 illustrates a perspective side view of a semiconductor structure.

FIG. 4 shows that the slot contact contains at least two parallel sub-contacts.

FIG. 5 is a perspective side view of a semiconductor structure according to another embodiment of the invention.

FIG. 6 is a schematic cross-sectional view taken along line II-II′ in FIG. 5.

FIG. 7 is a schematic cross-sectional view taken along line III-III′ in FIG. 5.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

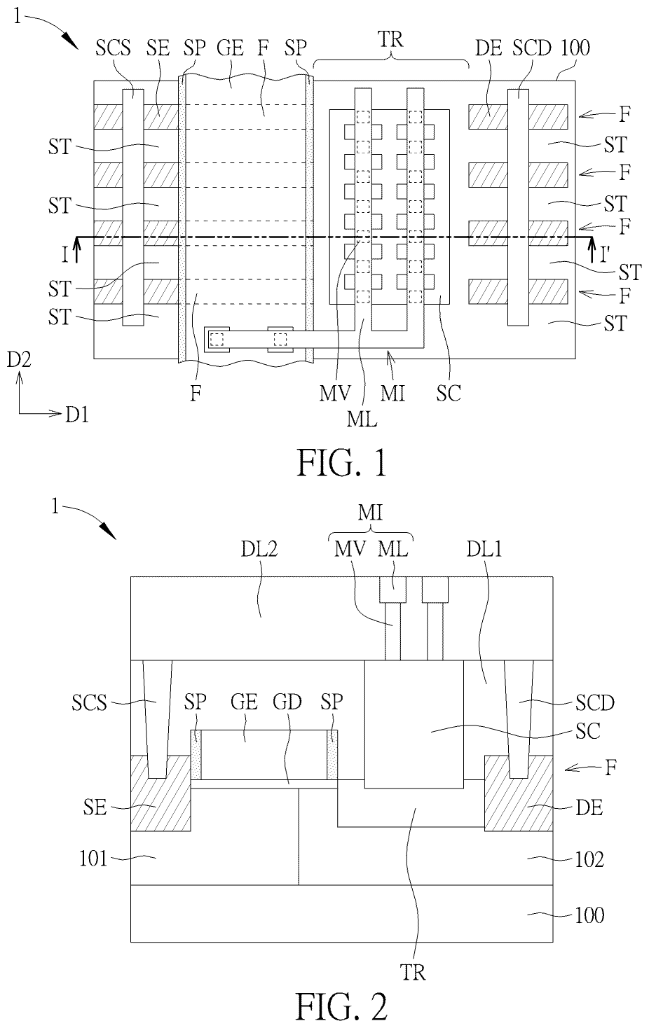

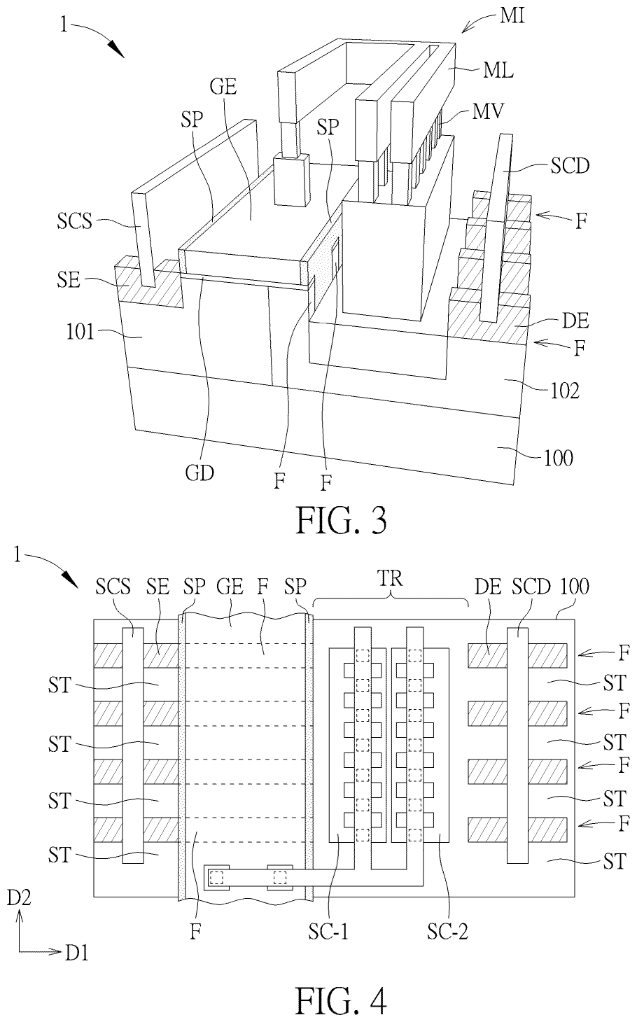

Please refer to FIG. 1 to FIG. 3. FIG. 1 is a partial top view of a semiconductor structure according to an embodiment of the present invention. FIG. 2 is a cross-sectional view taken along line I-I′ in FIG. 1. FIG. 3 illustrates a schematic cross-sectional view of the semiconductor structure. For the sake of simplicity, the interlayer dielectric layers are omitted in FIG. 3. The high-voltage semiconductor structure illustrated in the figures may be a laterally diffused metal oxide semiconductor (LDMOS) transistor compatible with a fin field effect transistor (finFET) process at 14 nm node or below.

As shown in FIG. 1 to FIG. 3, the semiconductor structure 1 includes a substrate 100, for example, a silicon substrate, having a plurality of fins F thereon. According to an embodiment of the present invention, a plurality of shallow trench isolation structures ST may be disposed between the plurality of fins F, and the plurality of fins F protrude from the upper surfaces of the shallow trench isolation structures ST. According to an embodiment of the present invention, for example, the fins Fare silicon fins, but are not limited thereto. According to an embodiment of the present invention, the plurality of fins F and shallow trench isolation structures ST may extend along the first direction D1.

According to an embodiment of the present invention, a first well 101 is provided in the substrate 100, where the first well 101 has a first conductivity type. According to an embodiment of the present invention, a second well 102 is further provided in the substrate 100, wherein the second well 102 has a second conductivity type. According to an embodiment of the present invention, the first conductivity type is, for example, P type, and the second conductivity type, for example, is N type. According to an embodiment of the invention, the second well 102 is adjacent to and contiguous with the first well 101. According to an embodiment of the present invention, the plurality of fins F partially overlaps the first well 101 and partially overlaps the second well 102.

According to an embodiment of the present invention, an epitaxial source region SE is provided on the plurality of fins F in the first well 101, where the epitaxial source region SE has a second conductivity type, for example, N type. According to an embodiment of the present invention, an epitaxial drain region DE is provided on the plurality of fins F in the second well 102, wherein the epitaxial drain region DE has a second conductivity type, for example, N type. According to an embodiment of the present invention, the epitaxial drain region DE is spaced apart from the epitaxial source region SE. According to an embodiment of the present invention, for example, the epitaxial source region SE and the epitaxial drain region DE may include SiP or SiGe, but are not limited thereto.

According to an embodiment of the present invention, a gate GE is provided on the plurality of fins F between the epitaxial source region SE and the epitaxial drain region DE. According to an embodiment of the present invention, the gate GE may be a metal gate, for example, a replacement metal gate. According to an embodiment of the present invention, the gate GE extends along the second direction D2. According to an embodiment of the present invention, for example, the first direction D1 is perpendicular to the second direction D2. According to an embodiment of the present invention, the gate GE may include spacers SP, for example, silicon nitride spacers. According to an embodiment of the present invention, the gate GE further includes a gate dielectric layer GD, such as silicon dioxide, but is not limited thereto.

According to an embodiment of the present invention, a trench isolation region TR is provided in the second well 102 between the gate GE and the epitaxial drain region DE. According to an embodiment of the present invention, the trench isolation region TR extends along the second direction D2 and cuts off a plurality of fins F between the gate GE and the epitaxial drain region DE. According to an embodiment of the present invention, as shown in FIG. 1, when viewed from above, the gate GE does not overlap the trench isolation region TR. According to an embodiment of the present invention, as shown in FIG. 2, the top surface of the trench isolation region TR is lower than the top surface of the epitaxial source region SE and the top surface of the epitaxial drain region DE.

According to an embodiment of the present invention, the trench isolation region TR may be formed together with the shallow trench isolation structures ST using a shallow trench isolation process, wherein the trench isolation region TR and the shallow trench isolation structure ST may include insulators such as silicon dioxide. According to an embodiment of the present invention, the bottom depth of the trench isolation region TR does not exceed the junction depth of the second well 102.

According to an embodiment of the present invention, a slot contact SC is provided on the trench isolation region TR. According to an embodiment of the present invention, for example, the slot contact SC may include tungsten, titanium, titanium nitride, or a combination thereof, but is not limited thereto. According to an embodiment of the present invention, the slot contact SC extends in the second direction D2. According to an embodiment of the present invention, the slot contact SC may have a grid structure to avoid a dishing effect caused by grinding or polishing, but is not limited thereto.

According to another embodiment of the present invention, as shown in FIG. 4, the slot contact SC may include at least two parallel sub-contacts SC-1 and SC-2, wherein the sub-contacts SC-1 and SC-2 are not directly connected to each other and may also have a grid structure, but is not limited thereto. In some embodiments, for example, the sub-contacts SC-1 and SC-2 may be solid structures.

According to an embodiment of the present invention, a slot contact SCS is provided on the epitaxial source region SE, and a slot contact SCD is provided on the epitaxial drain region DE, wherein the slot contact SCS and the slot contact SCD may extend along the second direction D2. According to an embodiment of the present invention, as shown in FIG. 2, the slot contact SC, the slot contact SCS and the slot contact SCD may be formed in the first dielectric layer DL1. According to an embodiment of the present invention, as shown in FIG. 2, a second dielectric layer DL2, such as a low dielectric constant material layer or an ultra-low dielectric constant material layer may be formed on the first dielectric layer DL1.

According to an embodiment of the present invention, the gate GE may be electrically connected to the slot contact SC through the metal interconnect structure MI formed in the second dielectric layer DL2. According to an embodiment of the present invention, the metal interconnect structure MI may include conductive vias MV and wires ML. According to another embodiment of the present invention, the gate GE may not be electrically connected to the slot contact SC, wherein the gate GE may be electrically coupled to a gate voltage V_{G}, and the slot contact SC may be electrically coupled to a contact voltage V_{C}, so they can be respectively controlled by altering the gate voltage V_{G} and contact voltage V_{C}.

One advantage of the present invention is that the voltage of the slot contact SC can be controlled to change the electric field below the trench isolation region TR, thereby reducing the on-resistance (RON) and improving the operating performance of the high-voltage devices.

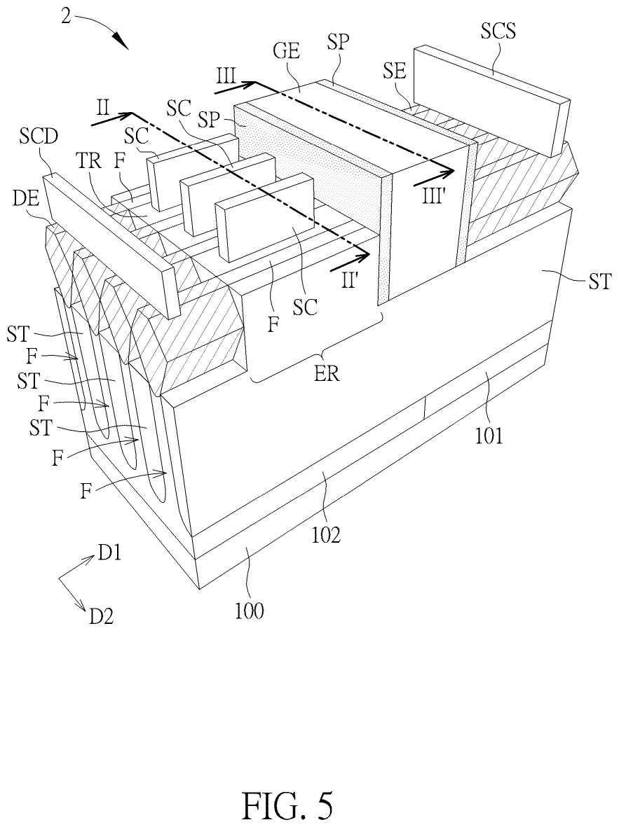

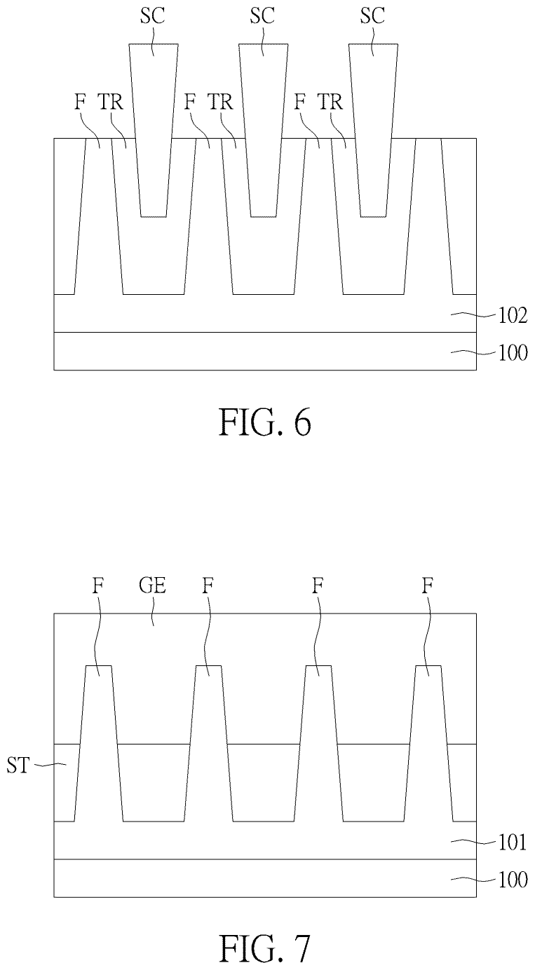

Please refer to FIG. 5 to FIG. 7. FIG. 5 is a perspective side view of a semiconductor structure according to another embodiment of the present invention. FIG. 6 is a schematic cross-sectional view taken along line II-II′ in FIG. 5. FIG. 7 is a schematic cross-sectional view taken along line III-III′ in FIG. 5, wherein like regions, materials, and layers are still designated by like numeral numbers or labels.

As shown in FIGS. 5 to 7, likewise, the semiconductor structure 2 comprises a substrate 100, such as a silicon substrate, having a plurality of fins F thereon. According to an embodiment of the present invention, a plurality of shallow trench isolation structures ST may be disposed between the plurality of fins F, and the plurality of fins F protrudes from the upper surfaces of the shallow trench isolation structures ST. According to an embodiment of the present invention, for example, the fins F are silicon fins, but are not limited thereto. According to an embodiment of the present invention, the plurality of fins F and shallow trench isolation structures ST may extend along the first direction D1.

According to an embodiment of the present invention, likewise, a first well 101 is provided in the substrate 100, where the first well 101 has a first conductivity type. According to an embodiment of the present invention, a second well 102 is further provided in the substrate 100, wherein the second well 102 has a second conductivity type. According to an embodiment of the present invention, the first conductivity type is, for example, P type, and the second conductivity type, for example, is N type. According to an embodiment of the invention, the second well 102 is adjacent to and contiguous with the first well 101. According to an embodiment of the present invention, the plurality of fins F partially overlaps the first well 101 and partially overlaps the second well 102.

According to an embodiment of the present invention, an epitaxial source region SE is provided on the plurality of fins F in the first well 101, where the epitaxial source region SE has a second conductivity type, for example, N type. According to an embodiment of the present invention, an epitaxial drain region DE is provided on the plurality of fins F in the second well 102, wherein the epitaxial drain region DE has a second conductivity type, for example, N type. According to an embodiment of the present invention, the epitaxial drain region DE is spaced apart from the epitaxial source region SE. According to an embodiment of the present invention, for example, the epitaxial source region SE and the epitaxial drain region DE may include SiP or SiGe, but are not limited thereto.

According to an embodiment of the present invention, gates GE are provided on the plurality of fins F between the epitaxial source region SE and the epitaxial drain region DE. According to an embodiment of the present invention, the gate GE may be a metal gate, for example, a replacement metal gate. According to an embodiment of the present invention, the gate GE extends along the second direction D2 and spans the plurality of fins F. According to an embodiment of the present invention, for example, the first direction D1 is perpendicular to the second direction D2. According to an embodiment of the present invention, the gate GE may include spacers SP, for example, silicon nitride spacers. According to an embodiment of the present invention, the gate GE further includes a gate dielectric layer GD, such as silicon dioxide, but is not limited thereto.

According to an embodiment of the present invention, a plurality of trench isolation regions TR are provided in the second well 102 between the gate GE and the epitaxial drain region DE. According to an embodiment of the present invention, the plurality of trench isolation regions TR may extend along the second direction D2. It can be seen from FIG. 5 that the plurality of trench isolation regions TR does not cut the plurality of fins F between the gate GE and the epitaxial drain region DE. According to an embodiment of the present invention, as shown in FIG. 5, when viewed from above, the gate GE does not overlap the plurality of trench isolation regions TR. According to an embodiment of the present invention, the plurality of trench isolation regions TR is disposed in the extended region ER between the gate GE and the epitaxial drain region DE. According to an embodiment of the present invention, in the extended region ER, the top surfaces of the trench isolation regions TR, the top surfaces of the epitaxial source regions DE, the top surfaces of the epitaxial drain regions SE, and the top surfaces of the plurality of fins F are coplanar.

According to an embodiment of the present invention, the plurality of trench isolation regions TR may be formed together with the shallow trench isolation structures ST using a shallow trench isolation process, wherein the plurality of trench isolation regions TR and the shallow trench isolation structures ST may include insulators such as silicon dioxide. According to an embodiment of the present invention, the bottom depth of the plurality of trench isolation regions TR does not exceed the junction depth of the second well 102.

According to an embodiment of the present invention, a plurality of slot contacts SC extending along the first direction D1 is respectively provided on the plurality of trench isolation regions TR. According to an embodiment of the present invention, for example, the plurality of slot contacts SC may include tungsten, titanium, titanium nitride, or a combination thereof, but is not limited thereto. According to an embodiment of the present invention, as can be seen from FIG. 6, the plurality of slot contacts SC respectively extends deep into the plurality of trench isolation regions TR to a predetermined depth. According to an embodiment of the present invention, the plurality of slot contacts SC is parallel to the plurality of fins F and do not directly contact the plurality of fins F.

According to an embodiment of the present invention, the gate GE may be electrically connected to the plurality of slot contacts SC via the metal interconnect structure MI as shown in FIG. 1. According to another embodiment of the present invention, the gate GE may not be electrically connected to the slot contact SC, wherein the gate GE may be electrically coupled to a gate voltage VG, and the slot contact SC may be electrically coupled to a contact voltage V_{C}, so they can be respectively controlled by altering the gate voltage VG and contact voltage V_{C}.

When the channel of the semiconductor structure 2, for example, a laterally diffused metal oxide semiconductor (LDMOS) transistor is turned on, the plurality of slot contacts SC extending into the plurality of trench isolation regions TR helps to attract more carriers to the sidewalls (drift areas) of the fins F thereby reducing the on-resistance (RON) and improve the operating performance of the high-voltage device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a substrate having a plurality of fins thereon, wherein the plurality of fins extends along a first direction;
a first well having a first conductive type disposed in the substrate;
a second well having a second conductive type disposed in the substrate, wherein the plurality of fins partially overlaps with the first well and partially overlaps with the second well;
an epitaxial source region having the second conductive type disposed on the plurality of fins within the first well;
an epitaxial drain region having the second conductive type disposed on the plurality of fins within the second well, wherein the epitaxial drain region is spaced apart from the epitaxial source region;
a gate disposed on the plurality of fins between the epitaxial source region and the epitaxial drain region, wherein the gate extends along a second direction;
a trench isolation region disposed within the second well between the gate and the epitaxial drain region, wherein the trench isolation region extends along the second direction and cuts off the plurality of fins between the gate and the epitaxial drain region; and
a slot contact disposed on the trench isolation region and extending along the second direction.

2. The semiconductor structure according to claim 1, wherein the gate does not overlap with the trench isolation region when viewed from above.

3. The semiconductor structure according to claim 1, wherein the gate is electrically connected to the slot contact.

4. The semiconductor structure according to claim 1, wherein the gate is not connected to the slot contact, wherein the gate is electrically coupled to a gate voltage and the slot contact is electrically coupled to a contact voltage.

5. The semiconductor structure according to claim 1, wherein the slot contact has a grid structure.

6. The semiconductor structure according to claim 1, wherein the slot contact comprises at least two parallel sub-contacts.

7. The semiconductor structure according to claim 1, wherein the trench isolation region has a top surface that is lower than a top surface of the epitaxial source region and a top surface of the epitaxial drain region.

8. The semiconductor structure according to claim 1, wherein the second well is contiguous with the first well.

9. The semiconductor structure according to claim 1, wherein the first conductivity type is P type and the second conductivity type is N type.

10. The semiconductor structure according to claim 1, wherein the gate is a metal gate.

11. A semiconductor structure, comprising:
a substrate having a plurality of fins thereon, wherein the plurality of fins extends along a first direction;
a first well having a first conductive type disposed in the substrate;
a second well having a second conductive type disposed in the substrate, wherein the plurality of fins partially overlaps with the first well and partially overlaps with the second well;
an epitaxial source region having the second conductive type disposed on the plurality of fins within the first well;
an epitaxial drain region having the second conductive type disposed on the plurality of fins within the second well, wherein the epitaxial drain region is spaced apart from the epitaxial source region;
a gate disposed on the plurality of fins between the epitaxial source region and the epitaxial drain region, wherein the gate extends along a second direction;
a plurality of trench isolation regions disposed within the second well between the plurality of fins, wherein the plurality of trench isolation regions extends along the first direction; and
a plurality of slot contacts respectively disposed on the plurality of trench isolation regions and extending along the first direction.

12. The semiconductor structure according to claim 11, wherein the plurality of trench isolation regions is disposed in an extended region between the gate and the epitaxial drain region, and wherein the gate does not overlap with the plurality of trench isolation regions when viewed from above.

13. The semiconductor structure according to claim 11, wherein the gate is electrically connected to the plurality of slot contacts.

14. The semiconductor structure according to claim 11, wherein the gate is not connected to the plurality of slot contacts, wherein the gate is electrically coupled to a gate voltage and the plurality of slot contacts is electrically coupled to a contact voltage.

15. The semiconductor structure according to claim 11, wherein the plurality of slot contacts extends into the plurality of trench isolation regions, respectively.

16. The semiconductor structure according to claim 11, wherein the plurality of slot contacts is in parallel with the plurality of fins.

17. The semiconductor structure according to claim 12, wherein the plurality of trench isolation regions has a top surface that is coplanar with a top surface of the epitaxial source region, a top surface of the epitaxial drain region, and a top surface of the plurality of fins within the extended region.

18. The semiconductor structure according to claim 11, wherein the second well is contiguous with the first well.

19. The semiconductor structure according to claim 11, wherein the first conductivity type is P type and the second conductivity type is N type.

20. The semiconductor structure according to claim 11, wherein the gate is a metal gate.
